(19) United States
(12) Patent Application Publication
(10) Pub. No.: US 2007/0070466 A1
(43) Pub. Date: Mar. 29, 2007

(54) Image forming apparatus

(75) Inventor: Hiroyuki Okuyama, Mishima-shi (JP)

Correspondence Address: FOLEY AND LARDNER LLP;SUITE 500, 3000 K STREET NW, WASHINGTON, DC, 20007, US

(73) Assignees: KABUSHIKI KAISHA TOSHIBA; TOSHIBA TEC KABUSHIKI KAISHA

(21) Appl. No.: 11/234,137

(22) Filed: Sep. 26, 2005

(51) Int. Cl. G03F 3/08

(52) U.S. Cl. 358/518; 358/1.15

(57) ABSTRACT

An image forming apparatus includes a color print section configured to make a color printing and a changing section configured to, when color data is printed by the color printer section, allow changing to a subtractive color printing or not according to attribute information.

### BACKGROUND OF THE INVENTION

1. Field of the Invention

The present invention relates to an image forming apparatus for making a subtractive color printing.

2. Description of the Related Art

A method is known in which, when input data from an external device such as a PC is printed by a digital color composite machine (hereinafter referred to as an MFP) or a color printer, this is done using a preset designated color and black color alone. For example, when a designated color is a blue color, the color contained in that input data is all converted to a blue color and a black color is printed as it is. At this time, magenta, cyan and black toners are used and no yellow color is used. It is, therefore, possible to suppress the consumption of the yellow toner and set a printing cost to a lower level. If such two-color printing is done, any exact color information on a document is lost upon the printing of data such as a character, a line drawing, etc. However, it is possible to achieve a printing object with an emphasized color. Hereinafter, this printing method is called “two-color printing”.

In the conventional two-color printing, the color information of a character, a line drawing, etc., is replaced by a designated color (cyan, magenta, yellow, red, green, blue, etc.) and the object of the printing can be achieved with an emphasized color. In a photo image, however, those colors other than an achromatic (black) color are all replaced by a designated color and an image becomes a black color/designated color mixed image and an outer visibility is markedly lowered. Further, in the case of the photo image, much more toner is normally consumed and it will become difficult to set the printing cost to a lower level at the time of such two-color printing.

There is, therefore, a growing need for an image forming apparatus which can set a printing cost to a lower level and obtain a good photo appearance.

### BRIEF SUMMARY OF THE INVENTION

According to an aspect of the present invention, there is provided an image forming apparatus comprising a color printer section configured to make a color printing and a changing section configured to, when color data is printed by the color printer section, allow changing to be effected to a subtractive color printing or not according to attribute information.

Objects and advantages of the invention will become apparent from the description which follows, or may be learned by practice of the invention.

### BRIEF DESCRIPTION OF THE SEVERAL VIEWS OF THE DRAWING

The accompanying drawings illustrate embodiments of the invention, and together with the general description given above and the detailed description given below, serve to explain the principles of the invention.

FIG. 1 is a view schematically showing a network arrangement in one embodiment of the present invention;

FIG. 2 is a view schematically showing a system arrangement of an image forming apparatus according to the present embodiment;

FIG. 3 is a view for explaining print processing when printing data is received in the present embodiment; and

FIG. 4 is a flowchart showing color convert processing at a subtractive color printing in the present embodiment.

### DETAILED DESCRIPTION OF THE INVENTION

With reference to the drawing, one embodiment of the present invention will be explained below.

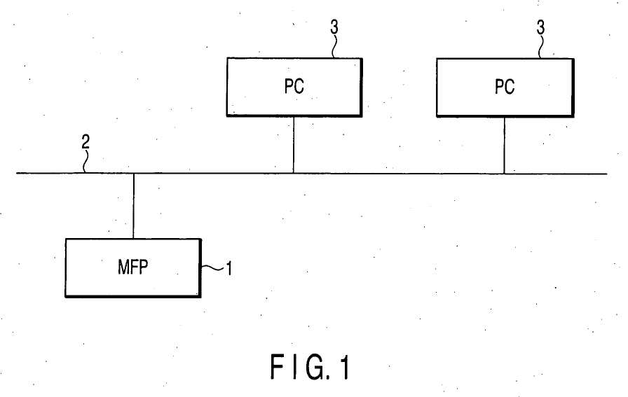

FIG. 1 is a view schematically showing a network arrangement relating to an embodiment. An MFP 1 is connected via a network 2 to personal computers (PC's) 3.

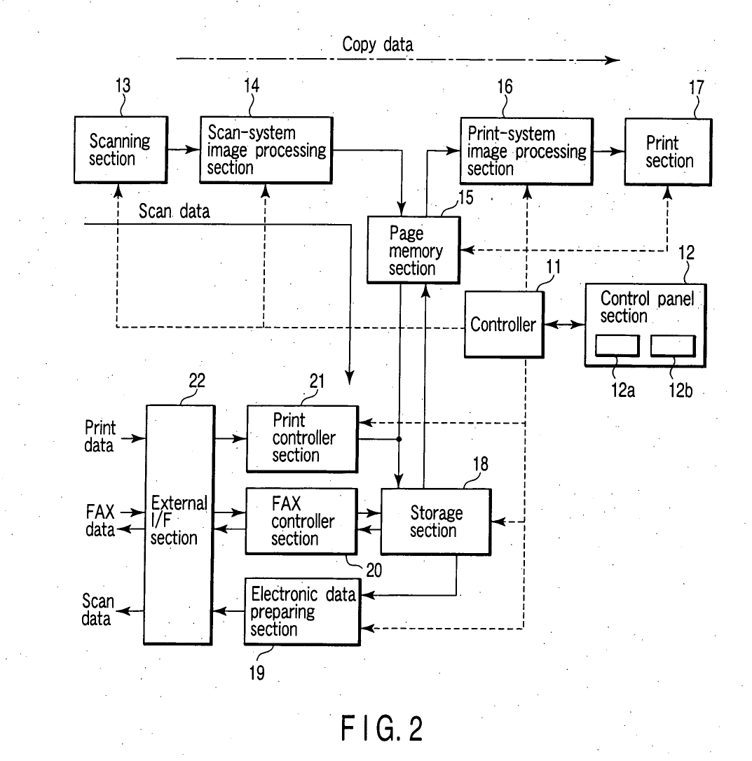

FIG. 2 is a view schematically showing a system arrangement of the MFP 1. The MFP has a controller 11, a control panel section 12, a scanning section 13, a scan-system image processing section 14, a page memory section 15, a print-system image processing section 16, a print section 17, a storage section 18, an electronic data preparing section 19, a FAX controller section 20, a printer controller section 21, and an external interface (I/F) 22 as shown in FIG. 2. By being so arranged, the MFP 1 can have a copy function, a printer function, a scanner function, a FAX function, a storage function, etc.

The controller 11 comprises a CPU, a memory, etc. Based on a control program and fixed data stored in the memory, the controller 11 controls the scanning section 13, scan-system image processing section 14, page memory section 15, print-system image processing section 16, a print section 17, storage section 18, electronic data preparing section 19 and printer controller section 21.

The control panel section 12 has an operation section 12a and a display section 12b. The operation section 12a transmits an instruction given from a user side to the controller 11. The instruction is, for example, an instruction relating to the scanning of a document image, an instruction relating to a copy and a FAX-transfer-relating instruction. Further, the display section 12b displays, under the control of the controller 11, information necessary to the user.

The scanning section 13 has a color CCD sensor, etc., and can read out a color image. Further, the scanning section 13 reads out an image from a document sheet, etc., on a document rest (not shown) and generates image data. And the scanning section 13 outputs the generated image data to the scan-system image processing section 14.

The scan-system image processing section 14 performs various kinds of processing, under the control of the controller 11, on the image data which is input from the scanning section 13. The scan-system image processing section 14 outputs the thus processed image data to the page memory section 15.

The page memory section 15 temporarily stores the image data which is input from the scan-system image processing section 14. And the page memory section 15 outputs the stored image data to the storage section 18. Further, the page memory section 15 temporarily stores the image data which is input from the storage section 18. The page memory section 15 outputs the stored image data to the print-system image processing section 16.

Under the control of the controller 11, the print-system image processing section 16 performs various kinds of processing on the image data which is input from the page memory section 15. Further, the print-system image processing section 16 outputs the thus processed image data to the print section 17.

The print section 17 allows printing to be made on a recording sheet based on the image data which is input from the print-system image processing section 16. The print section 17 can print a color image on the recording sheet with the use of, for example, four color toners of cyan, magenta, yellow and black.

Upon receipt of the image data which is scan-system image processed from the page memory section 15, the storage section 18 stores that image data. In the storage section 18, this stored image data is output to the electronic data preparing section 19 if a scanning instruction is received from the operation section 12a by the operation of the user. In the storage section 18, the stored image data is output to the page memory section 15 if a copy instruction is given from the user on the operation section 12a and, further, if a FAX instruction is received from the user on the operation section 12a, the stored image data as set out above is output to the FAX controller section 20. Further, the storage section 18 stores image data which is output from the printer controller or image data which is input from the FAX controller section 20. The storage section 18 outputs thus stored image data to the page memory section 15.

The electronic data preparing section 19 performs processing on image data from the storage section 18 to allow it to be output as scan data to an outside and prepares electronic data. Further, based on the user's instruction from the operation section 12a or an instruction from the PC 3 on the network 2, electronic data is output through the external I/F section 22 to a designated output destination.

The FAX controller section 20 performs processing on the image data from the storage section 18 to allow it to be output as FAX data to an outside. Based on an instruction from the operation section 12a, the FAX controller section 20 outputs the FAX data to a designated output destination through the external I/F section 22. The FAX controller section 20 performs predetermined processing on the FAX data input through the external I/F section 22 and generates image data. And the FAX controller section 20 outputs the generated image data to the storage section 18.

The printer controller section 21 receives PDL data from PC 3 through the external I/F section 22, that is, PDL data described by a predetermined page description language (PDL), and performs processing on the PDL data. This processing will be described later. And the printer controller section 21 outputs the processed image data as set out above to the storage section 18.

The external I/F section 22 is connected to the network 2 and allows data communication to be made with an external device such as the PC connected to the network 2. The external I/F section 22 allows, for example, print data which is transmitted from the PC to be received, FAX data to be received/transmitted and scan data to be output.

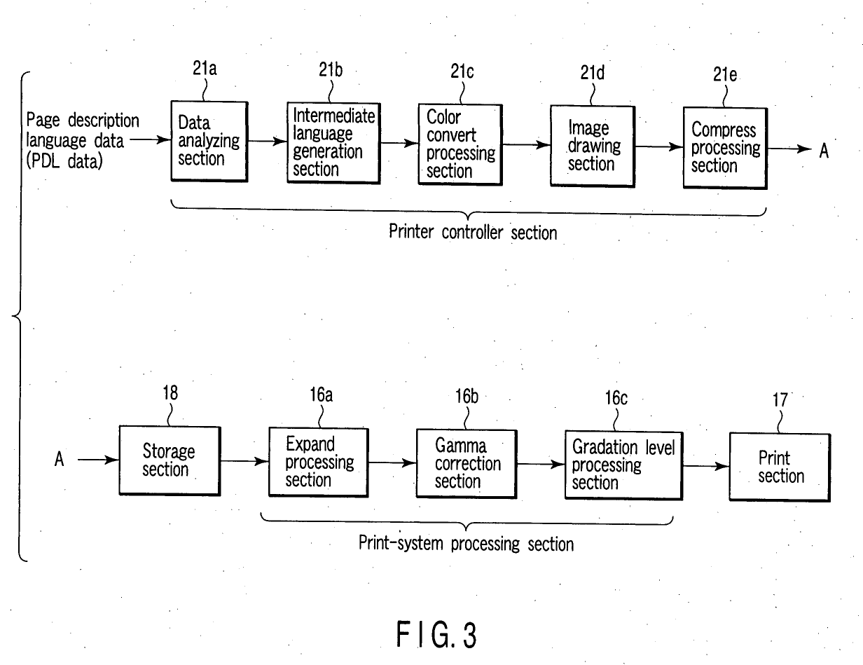

Next, an explanation will be made about the processing of the above-mentioned printer controller section 21 when the PDL data is received from the PC 3 via the external I/F section 22. FIG. 3 is a view for explaining the processing performed when the PDL data is received.

First, an explanation will be made about the processing done in the printer controller section 21. As shown in FIG. 3, the kind of PDL data which is input from the PC 3 is identified in the data analyzing section 21a in the printer controller section. A result of such identification is made to correspond as attribute information to PDL data. Here, the attribute information represents font information such as a character, graphics information such as a line drawing and image information such as an image. Hereinafter, the font information, graphics information and image information are generally called an object. In this connection, it is to be noted that those attribute information items further classified and those information items associated with the PDL data are also handled as attribute information. As a latter example, toner save information representing “toner save enable/disable” information used at the printing of a document image, document mode information used for the designation of the kind of documents to be input, designation color information at a time of two-color printing, and so on, are listed by way of example. The designation color information at the time of such two-color printing constitutes the color information at the two-color printing which is designated by a printer driver of the PC 3 for a subtractive color printing. The PDL data is subjected to analyze-processing by the data analyzing section 21a and, after intermediate language generation by an intermediate language generation section 21b, is subjected by a color-convert processing section 21c to adaptive color-convert processing based on the designation color information and attribute information.

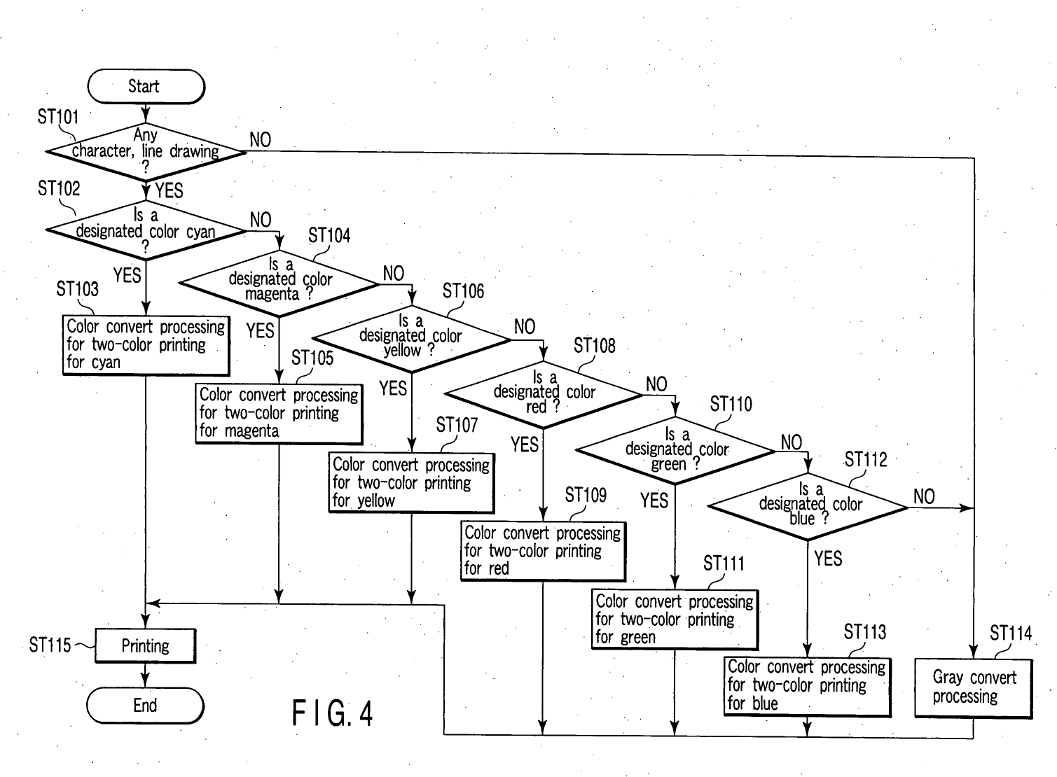

Now, an explanation will be made about performing an adaptive color-convert processing based on the designation color information and attribute information. FIG. 4 is a flowchart showing the color-convert processing for two-color printing for a subtractive color.

First, it is decided whether the attribute represented by the attribute information of received PDL data is a character or a line drawing (ST 101). Stated in more detail, this decision is made based on whether an object corresponding to the PDL data is the font information or graphics information.

If the attribute is decided as being a character or a line drawing (YES at ST 101), it is decided whether or not a designated color represented by designation color information is cyan (ST 102). If the designated color is decided as being cyan (YES at ST 102), color-convert processing is performed for two-color printing for cyan (ST 103). If the designated color is decided as not being cyan (NO at ST 102), it is decided whether or not the designated color represented by the designation color information is magenta (ST 104). If the designated color is decided as being magenta (YES at ST 104), color-convert processing is performed for two-color printing for magenta (ST 105). If the designated color is decided as not being magenta (NO at ST 104), it is decided whether or not the designated color represented by the designation color information is yellow (ST 106). If the designated color is yellow (YES at ST 106), color-convert processing is performed for two-color printing for yellow (ST 107). If the designated color is not yellow (NO at ST 106), it is decided whether or not a designated color represented by the designation color information is red (ST 108). If the designated color is red (YES at ST 108), color-convert processing is done for two-color printing for red (ST 109). If the designated color is decided as not being red (NO at ST 108), it is decided whether or not the designated color represented by the designation color information is green (ST 110). If the designated color is decided as being green (YES ST at 110), color-convert processing is performed for two-color printing for green (ST 111). If the designated color is decided as not being green (YES at ST 110), it is decided whether or not the designated color represented by the designation color information is decided as being blue (ST 112). If the designated color is decided as being blue (YES at ST 112), color-convert processing is performed for two-color printing for blue (ST 113).

If the designated color is decided as not being blue (NO at ST 112) or the attribute represented by the attribute information is not any font or drawing line (NO at ST 101), that is, if the object is image information, gray-convert processing is done (ST 114).

In this way, the specific colors are designated for two-color printing and, with the use of a color conversion table corresponding to the designated colors, color-convert processing is performed on the PDL data whose corresponding object is font information or graphics information. In this color conversion table, the color information are all replaced by the designated color and the other color “black” is output as it is.

Further, the specific color is designated for two-color printing and, with respect to the PDL data whose corresponding object is the image information, all image areas are output as the black color Black by use of an equation (1) below.
Black=255−(α×Red+β×Green+γ×Blue) (1)

Here, in the equation (1), α, β, γ, represent weighted coefficients taking a value of 0 to 1, and Red, Green, Blue represent image data. By this, gray processing is done.

After all the processing are done on the PDL data, an image drawing section 21d generates raster image data. The raster image data is converted to coded data by a compress processing section 21e. And the printer controller section 21 outputs the coded data to the storage section 18. In this way, the processing is completed in the printer controller section 21.

The storage section 18 once saves the coded data which is input from the printer controller section 21. The storage section 18 outputs the coded data to the page memory section 15. The page memory section 15 once saves the coded data which is input from the storage section 18. The saved coded data is output to the print-system image processing section. In the print-system image processing section 16, an expand processing section 16a converts the coded data again to the raster image data. In the printer-system image processing section 16, gamma correction processing is done by a gamma correction section 16b on the raster image data and gradation level processing is done by a gradation processing section 16c on it. The thus processed raster image data is output from the print-system image processing section 16 to the print section 17. The print section 17 forms an image on a recording sheet based on the input data from the print-system image processing section 16.

If, upon receipt of the PDL data in designation color information and attribute information from the PC 3, an object represented by the attribute information is font information or graphics information, the MFP 1 performs two-color printing with a color designated by designation color information and black. If, upon receipt of the PDL data, an object represented by the attribute information is image information, the MFP 1 never makes any two-color printing with the designation color information, performs gray-convert processing, and makes printing based on the gray-convert processed data.

By, at the time of two-color printing, changing a color conversion method according to an object contained in the PDL data, it is possible to print the PDL data with a gray color alone in the case of the object being the image information. For this reason, the character and line drawing can be printed in two colors and, at the same time, an image can be printed in gray. It is, therefore, possible to largely improve the visibility of a photo image involved.

That is, according to the prevent embodiment, when the PDL data is subtractive-color printed under the color printer function of the MFP 1, it is possible to, according to the attribute information, make two-color printing or gray printing. It is, therefore, possible to make gray printing on those areas not originally desired to be printed in two colors and largely improve the appearance of a photo.

Although, in the above-mentioned embodiment, the MFP 1 has been explained as receiving the PDL data containing the attribute information and designation color information from the PC 3, the present invention can also be applied to the case of reading out any document image by the scanning section 13. For example, there is a case where a copy instruction and two-color printing designation can be given by the user on the operation section 12a. In this case, the scanning section 13 is so configured as to allow identify-processing to be made of whether scanned image data is a character, graphics or an image. In this case, a result of processing is made to correspond to the image data which is scanned as the attribute information (object). And, at the time of printing the image data, changing is made to a two-color printing or a gray printing according to the attribute information. Even if, in this case, the object is image information, scanned image data can be printed as a gray print. It is, therefore, possible to print characters and line drawing in two colors and an image in gray color. And to largely improve the outer visibility of a photo image involved.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the invention as defined by the appended claims and equivalents thereof.

What is claimed is:

1. An image forming apparatus comprising:
a color print section configured to make color printing; and
a changing section configured to, when color data is printed by the color printing section, allow changing to be effected to subtractive color printing or not according to attribute information.

2. An image forming apparatus according to claim 1, further comprising an interface configured to be connected to an external device and wherein the color data being contained in printing data which is received via the interface from the external device.

3. An image forming apparatus according to claim 1, wherein the attribute information is font information representing a character, graphics information representing a line drawing or image information representing an image.

4. An image forming apparatus according to claim 3, wherein the attribute information further contains designation color information for designating a color for the subtractive color printing.

5. An image forming apparatus according to claim 4, further comprising a processing section configured to, if the attribute information is any of font information and graphics information when the subtractive color printing is made using the color data based on a designated color represented by the designation color information, perform subtractive-color print processing on the color data and, if the attribute information represents image information, perform gray convert processing on the color data and wherein the color print section allowing printing to be made based on the processed color data.

6. An image forming apparatus according to claim 1, further comprising a scanning section configured to scanning a document image and wherein the color data is based on an image scanned by the scanning section.

7. An image forming apparatus comprising:
color print means for making color printing;
changing means for, when color data is printed by the color printer means, allowing changing to be effected to subtractive color printing or not according to attribute information.

8. An image forming apparatus according to claim 7, further comprising connection means for allowing a connection to be made to an external device and wherein the color data is contained in printing data which is received from the external device via the connection means.

9. An image forming apparatus according to claim 7, wherein the identifying information is any of font information representing a character, graphics information representing a line drawing or image information representing an image.

10. An image forming apparatus according to claim 9, wherein the attribute information further contains designation color information for designating a color for subtractive color printing.

11. An image forming apparatus according to claim 10, further comprising processing means for, if the attribute information is any of font information and graphics information when subtractive color printing is made using the color data based on a designated color represented by the designation color information, performing subtractive color print processing on the color data and, if the attribute information is image information, gray convert processing on the color data, wherein the color print means allowing printing to be made based on the processed color data.

12. An image forming apparatus according to claim 7, further comprising scanning means for scanning an image from a document and wherein the color data is based on the image scanned by the scanning means.

13. A method for making subtractive color printing of a color image in an image forming apparatus having a color printer section for printing color data comprising
enabling changing to be effected to a subtractive color printing or not according to attribute information when the color data is printed.

14. A method according to claim 13, further comprising, receiving print data containing the color data from an external device connected via an interface.

15. A method according to claim 13, wherein the identifying information is font information representing a character, graphics information representing a line drawing or image information representing an image.

16. A method according to claim 15, wherein the attribute information contains designation color information for designating a subtractive color for a subtractive color printing.

17. A method according to claim 16, further comprising, if the attribute information is any of font information and graphics information, performing subtractive color print processing on the color data and, if the attribute information is image information, performing gray print processing on the color data.

18. A method according to claim 13, scanning an image from a document to generate data containing color data.
